(19) United States
(12) Patent Application Publication
(10) Pub. No.: US 2021/0307202 A1
(43) Pub. Date: Sep. 30, 2021

(54) ADDITIVE MANUFACTURED HEAT SINK

(71) Applicant: MAGNA INTERNATIONAL INC., Aurora (CA)

(72) Inventors: Vito ABATE, Etobicoke (CA); Jason DURFEE, Troy, MI (US); Todd DEAVILLE, Markham (CA)

(21) Appl. No.: 17/345,740

(22) Filed: Jun. 11, 2021

Related U.S. Application Data
(63) Continuation of application No. PCT/US2021/017642, filed on Feb. 11, 2021.
Application No. PCT/US2021/017642 is a continuation-in-part of application No. PCT/US2019/065768, filed on Dec. 11, 2019.
(60) Provisional application No. 62/975,549, filed on Feb. 12, 2020.
(60) Provisional application No. 62/778,637, filed on Dec. 12, 2018.

(51) Int. Cl. H05K 7/20

(52) U.S. Cl. CPC H05K 7/20336; B33Y 80/00; H05K 7/20427

(57) ABSTRACT

A heat sink includes a baseplate of thermally-conductive material and a radiator for transferring heat to atmosphere around the radiator. The baseplate is configured to be in thermal communication with a heat source, such as an integrated circuit or a power electronic device. The radiator is disposed upon the baseplate and includes a skin of melted material formed by additive manufacturing which encloses a chamber. An outer wick of porous material is disposed within the chamber, the outer wick coats an inner surface of the skin. A refrigerant is disposed within the chamber. The refrigerant changes between a liquid phase and a vapor phase to convey heat from the baseplate to the skin, and is conveyed back through the wick in the liquid phase by capillary action. The radiator also includes a plurality of fins extending from a cover to promote heat transfer to the atmosphere.

### CROSS-REFERENCE TO RELATED APPLICATIONS

This application is a Continuation of PCT International Application No. PCT/US2021/017642 filed on Feb. 11, 2021, and titled “Additive Manufactured Heat Sink”, which claims the benefit of and priority to U.S. Provisional Patent Application Ser. No. 62/975,549 filed on Feb. 12, 2020, the entire disclosures of which are hereby incorporated by reference. This application is also a Continuation-In-Part of PCT International Application No. PCT/US2019/065768 filed on Dec. 11, 2019, and titled “Additive Manufactured Heat Sink,” which claims the benefit of and priority to U.S. Provisional Patent Application Ser. No. 62/778,637, filed Dec. 12, 2018, the entire disclosures of which are hereby incorporated by reference.

### FIELD

The present disclosure relates generally to a heat sink for conveying heat from a baseplate to a cover. More specifically, it relates to a heat sink produced by additive manufacturing.

### BACKGROUND

Heat skinks are used to convey heat away from a heat source, such as an electronic device, to prevent the heat source and/or other components from being damaged due to excessive temperatures. One type of heat skink that is conventionally known is a heat pipe, which uses a refrigerant fluid that changes from a liquid to a gas at an evaporator to transmit heat from the heat source to a condenser, where heat exits as the refrigerant fluid condenses back to a liquid. Conventional heat pipes employ a wick to transfer the condensed refrigerant from the condenser back to the evaporator.

Additive manufacturing is used to manufacture parts in a series of steps by progressively adding material to the part being manufactured. One type of conventional additive manufacturing uses a heat source, such as a laser, to melt a source material, such as a metal powder. Typically, the source material is removed from areas where it is not melted. This allows parts to be made with a variety of complex shapes.

### SUMMARY

A heat sink including a baseplate of thermally-conductive material defining a lower surface for conducting heat from a heat source is provided. The heat sink also includes a radiator disposed upon the baseplate away from the lower surface. The radiator includes a skin of melted material formed by additive manufacturing and enclosing a chamber. An outer wick of porous material is disposed within the chamber, the outer wick coats an inner surface of the skin. The outer wick has a physical property that varies over a distance from the baseplate.

A method of forming a heat sink is also provided. The method of forming a heat sink comprises: selectively melting a source material to form a skin defining a chamber of a radiator; forming the source material to define an outer wick of porous material within the chamber coating an inner surface of the skin; and attaching a baseplate of thermally-conductive material to the radiator to enclose the chamber, wherein the baseplate is configured to be in thermal communication with a heat source. The outer wick of porous material defines a physical property that varies as a function of distance from the baseplate.

### BRIEF DESCRIPTION OF THE DRAWINGS

Further details, features and advantages of designs of the invention result from the following description of embodiment examples in reference to the associated drawings.

FIG. 1 is a side cut-away view of a heat sink according to some embodiments of the present disclosure;

FIG. 2 is a side cut-away view of a heat sink according to some embodiments of the present disclosure;

FIG. 3 is a side cut-away view of a heat sink according to some embodiments of the present disclosure;

FIG. 4A is a side cut-away view of a heat sink according to some embodiments of the present disclosure;

FIG. 4B is an enlarged view of a portion of FIG. 4A;

FIG. 5A is a side view of a heat sink according to some embodiments of the present disclosure;

FIG. 5B is a cross-sectional view of the heat sink of FIG. 5A through section A-A;

FIG. 5C is a cross-sectional view of the heat sink of FIG. 5A through section B-B;

FIG. 6A is a top view of a heat sink according to some embodiments of the present disclosure;

FIG. 6B is a cross-sectional view of the heat sink of FIG. 6A through section A-A;

FIG. 6C is a cross-sectional view of the heat sink of FIG. 6A through section B-B;

FIG. 7 is a cut-away perspective view of a heat sink according to some embodiments of the present disclosure;

FIG. 8 is a perspective view of a heat sink according to some embodiments of the present disclosure.

FIG. 9 is a flow chart listing steps in a method of forming a heat sink; and

FIG. 10 is a flow chart listing steps in a method of dissipating heat by a heat sink.

### DETAILED DESCRIPTION

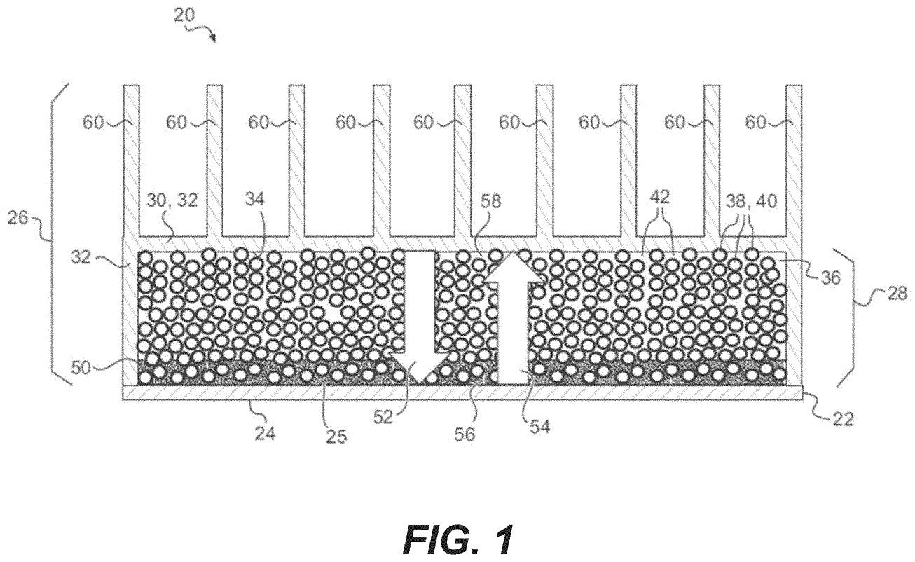

Recurring features are marked with identical reference numerals in the figures, in which example embodiments of a heat sink 20, 120, 220 are disclosed. FIG. 1 shows a first example heat sink 20 that includes a baseplate 22 of thermally-conductive material for conducting heat from a heat source. The baseplate 22 is shaped as a flat plate extending between a lower surface 24 and an upper surface 25. The lower surface 24 of the baseplate 22 is configured to be in thermal communication with a heat source, such as an integrated circuit or a power electronic device. The heat sink 20, 120, 220 also includes a radiator 26 disposed upon the upper surface 25 of the baseplate 22, away from the lower surface 24 for transferring heat to atmosphere, such as air or liquid that surrounds the radiator 26. The radiator 26 may transfer heat to the atmosphere by any means such as radiation, conduction, and/or convection. The radiator 26 includes a skin 32 of melted material formed by additive manufacturing, with the skin 32 and enclosing a chamber 36. For example, the skin 32 may be formed by selectively melting a source material, such as a loose powder, using a concentrated heat source, such as a laser.

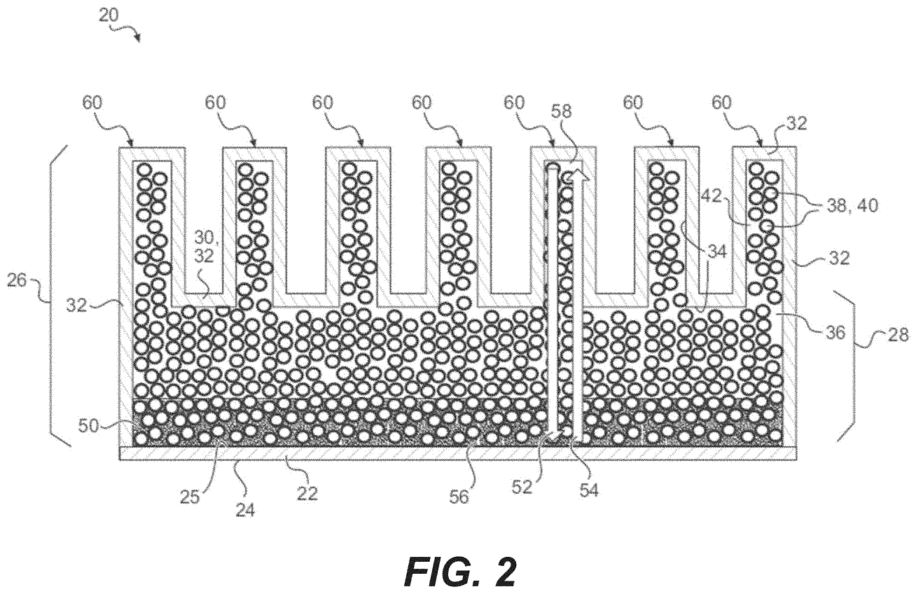

The heat sink 20, 120, 220 also includes an outer wick 38 of porous material disposed within the chamber 36 and coating an inner surface 34 of the skin 32. The outer wick 38 is permeable to liquid, allowing liquid and/or gases to flow therethrough with relatively low restrictions to flow. In some embodiments, and a shown in shown in FIGS. 1-2, the outer wick 38 comprises a permeable filling including loose granules 40 disposed within the chamber 36. The permeable filling may completely fill the chamber 36 as shown in FIGS. 1-2. Alternatively, the permeable filling may only partially fill the chamber 36. The loose granules 40 define void spaces 42 therebetween. The permeable filling may be, for example, a loose powder or a porous solid. In some embodiments, the permeable filling includes the source material in an unmelted state. For example, an outermost area of the source material may be melted to form the skin 32, and source material located therein may be left in an unmelted state or in a semi-melted state to form the permeable filling.

In some embodiments, the permeable filling may be entirely comprised of the source material. In other embodiments, the permeable filling may include the source material with one or more other components, which may be added after the skin 32 is formed by the additive manufacturing process. In other embodiments, the permeable filling may include none of the source material. For example, the permeable filling may be entirely made of material that is added after the skin 32 is formed by the additive manufacturing process. The permeable filling is permeable to liquid flow, allowing a liquid or a gas to pass therethrough. The permeable filling could include other structural components, such as, for example, a lattice or a foam or a compacted solid of granules with void spaces 42 therebetween. For example, the permeable filling may comprise a combination of loose granules and another liquid-permeable material such as a lattice or a foam or a compacted solid. The permeable filling preferably functions as a porous wick, promoting capillary action to convey liquid therethrough. In some embodiments, the permeable filling provides the heat sink 20, 120, 220 with structural rigidity, which may counteract air pressure force on the baseplate 22, the cover 30, and/or the skin 32. This may be especially useful in embodiments where the chamber 36 is under a vacuum.

In some embodiments, and as shown in FIGS. 1-2, the radiator 26 includes a foundation 28 that extends between the baseplate 22 and a cover 30 that is spaced apart from the baseplate 22. One or both of the baseplate 22 and/or the cover 30 may be made by melting the source material by additive manufacturing. Alternatively or additionally, the baseplate 22 and/or the cover 30 may be made independently and/or by a different process, such as by stamping, casting, machining, etc. In some embodiments, all or part of the skin 32 forms the cover 30. In some embodiments, the cover 30 is generally flat and is parallel and spaced apart from the baseplate 22. However, the cover 30 may have different shapes or orientations, depending on packaging requirements and/or heat dissipation requirements. The foundation 28 may be hollow, defining the chamber 36 therein. In some embodiments, the foundation 28 may be partially or completely filled with material.

In some embodiments, and as shown in FIGS. 1-2, a refrigerant 50 is disposed within the chamber 36. The refrigerant 50 may be free to flow through the outer wick 38. The outer wick 38 may hold the refrigerant 50 near the skin 32, thereby improving the ability of the heat sink 20, 120, 220 to dissipate heat. The refrigerant 50 may boil, or change between a liquid phase 52 and a vapor phase 54 to convey heat from the baseplate 22 to the cover 30. For example, the refrigerant 50 may boil from a first region 56 proximate to the baseplate 22 and travel in the vapor phase 54 to a second region 58 proximate to the cover 30. At the second region 58, the refrigerant 50 may condense back to the liquid phase 52. The refrigerant 50 in the liquid phase 52 may be conveyed through the void spaces 42 within the loose granules 40 and back to the first region 56 proximate to the baseplate 22 by capillary action.

In some embodiments, and as shown in FIGS. 1-2, the radiator 26 includes a plurality of fins 60 extending away from the baseplate 22. More specifically, the cover 30 may extend in a generally flat plane, with the plurality of fins 60 extending generally transversely to the generally flat plane. The cover 30 could define one or more curved surfaces, which may or may not include the fins 60 extending therefrom. The fins 60 may be formed as pillars or posts. Alternatively or additionally, the fins 60 may be formed as ribs that extend for a substantial length along the cover 30. The fins 60 may function to increase the surface area of the skin 32 to promote heat transfer to a fluid, such as a gas or a liquid, contacting an outer surface of the skin 32 opposite the chamber 36.

In some embodiments, and as shown in FIG. 1, the fins 60 is solid. In some other embodiments, and as shown in FIG. 2, the outer wick 38 extends into the fins 60. In some embodiments, and as shown for example in FIG. 2, the fins 60 are filled with the permeable material, which may be in fluid communication with the permeable material within the foundation 28. In this way, the refrigerant 50, in the vapor phase 54, can travel into the fins 60 to reach the second region 58, which is sufficiently cold to cause the vapor 54 to condense back to the liquid phase 52.

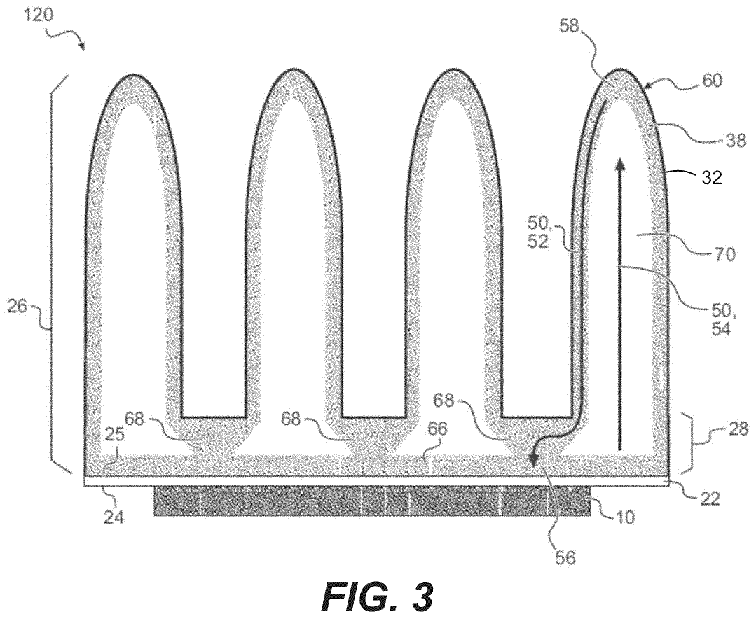

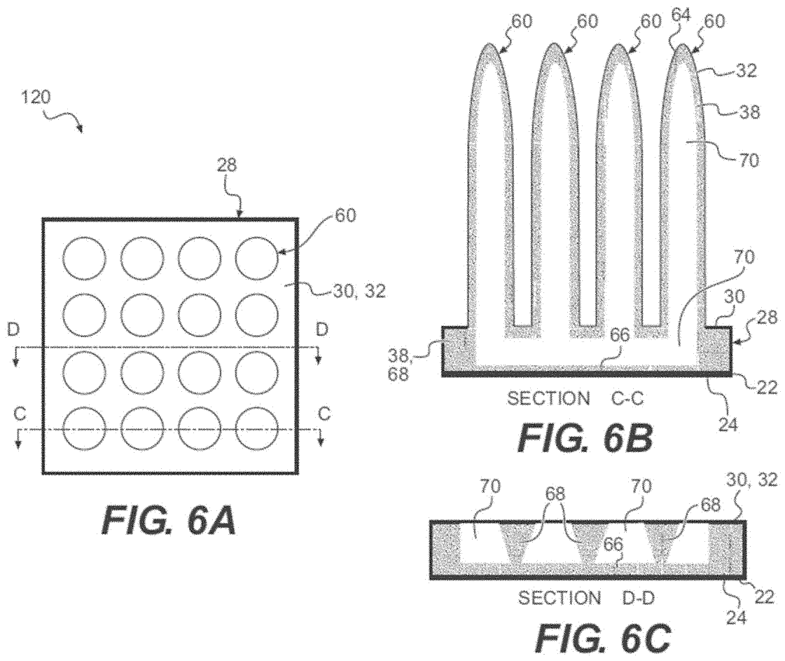

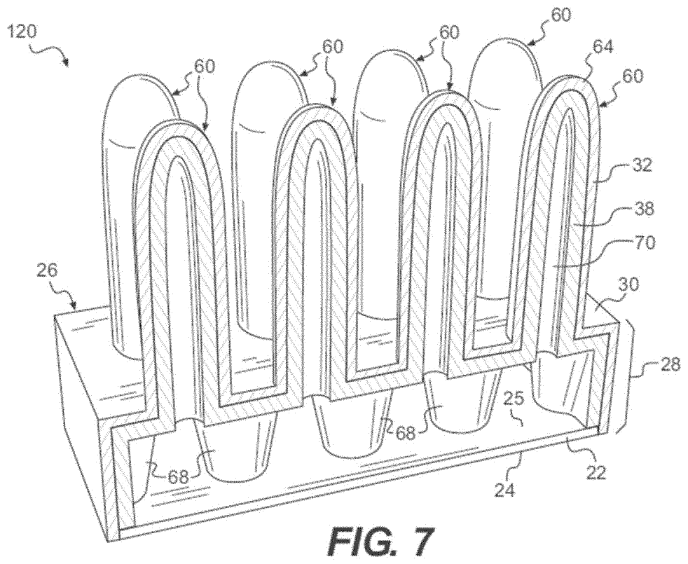

FIGS. 3-4, 5A-5C, 6A-6C, and 7 show a second example heat sink 120. The second example heat sink 120 is similar to the first example heat sink 20, with some additional design features. In some embodiments, the radiator 26 is formed as a monolithic piece by additive manufacturing. Similarly to the first example heat sink 20, the second example heat sink 120 includes an outer wick 38 of porous material disposed within the chamber and coating an inner surface 34 of the skin 32. In some embodiments, the outer wick 38 comprises material melted or partially melted material by additive manufacturing.

The second example heat sink 120 shown in FIGS. 3-7 includes a plurality of fins 60 extending away from the baseplate 22. In some embodiments, at least one of the fins 60 comprises a body 62 shaped as a rod or a cone extending away from the baseplate 22 to a closed top 64. For example, the body 62 of one of the fins 60 may be shaped as a cylinder that extends for an entire length between the cover 30 and the closed top 64. In another example, the body 62 of one of the fins 60 may taper down from a first cross-sectional area at the cover 30 to a second, smaller cross-sectional area at the closed top 64.

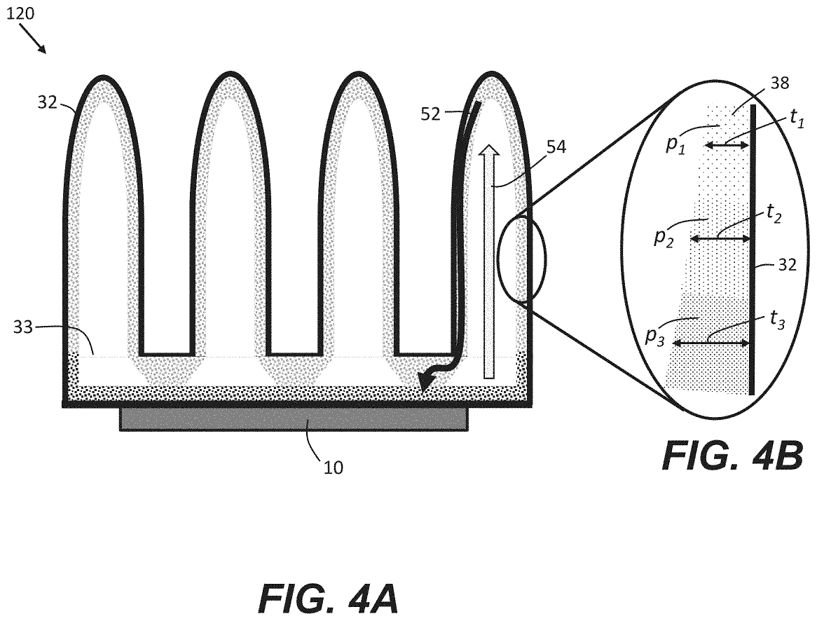

In some embodiments, and as shown in FIGS. 3-4, the heat sink 20, 120, 220 includes an inner wick 66 of porous material disposed within the chamber 36 and coating the upper surface 25 of the baseplate 22. In some embodiments, the inner wick 66 may be integrally formed with the baseplate 22, for example as a monolithic piece. Alternatively, the inner wick 66 may be formed separately from the baseplate 22. In some embodiments, and as shown in FIGS. 3-4, the heat sink 20, 120, 220 includes an intermediate wick 68 of porous material disposed within the chamber 36 between the outer wick 38 and the inner wick 66 for conveying liquid therebetween. In some embodiments, and also as shown in FIGS. 3-4, the radiator 26 defines a cavity 70 that extends between the inner wick 66 adjacent to the baseplate 22 into the fins 60. The cavity 70 may extend up into the closed top 64 of the fins 60. The vapor phase 54 of the refrigerant 50 may travel through the cavity 70 from the inner wick 66 and into the fins 60, where it condenses into the liquid phase 52. The liquid phase 52 of the refrigerant may condense within the outer wick 38 and return to the inner wick 66 via the intermediate wick 68 by gravity and/or by capillary action.

Any or all of the wicks 38, 66, 68 may be formed by additive manufacturing (AM). In some embodiments, each of the wicks 38, 66, 68 may be formed together with the skin 32 from shared source material. For example, a first melting power and/or speed may be used to create the skin 32, which impermeable, and a second, lower melting power and/or a higher speed may be used to create any or all of the wicks 38, 66, 68, which are permeable to liquid flow. In some embodiments, paths used in the AM process between adjacent layers may be rotated to form an open lattice type structure within one or more of the wicks 38, 66, 68.

In some embodiments, and as shown in FIG. 3, the baseplate 22 may comprise a solid piece of material, such as metal. Alternatively, the baseplate may comprise an insulated metal substrate (IMS) printed circuit board, such as ThermalClad by Henkel.

In some embodiments, the baseplate 22 may be attached to the radiator 26 after the radiator 26 is formed. In some embodiments, unmelted source material may be removed from the radiator 26 prior to attaching the baseplate 22 thereto, thus forming the cavity 70 within the radiator 26. The baseplate 22 may be welded to the radiator 26 to hermetically seal the chamber 36. Alternatively or additionally, the baseplate 22 may be attached to the radiator 26 by other means such as using an adhesive and/or using one or more fasteners.

FIGS. 4A-4B show a side cut-away view of a heat sink 120 with an outer wick 38 having one or more physical properties that vary over distance from the baseplate 22. In some embodiments, and as shown in FIG. 4A, the heat sink 120 may be partially or completely filled with source material 33 in a partially-melted and/or in an unmelted state. Such unmelted source material may be called “green” powder. The unmelted source material 33 may further enhance heat transfer from the baseplate 22 to the skin 32.

FIG. 4B is an enlarged sectional view of a portion of FIG. 4A. In some embodiments, one or more of the physical properties may vary in discrete steps. Alternatively or additionally, one or more of the physical properties may vary continuously over distance from the baseplate 22. For example, a thickness t of the outer wick 38 may vary in discrete steps, linearly, exponentially, or in some other function of distance. In some embodiments, and as shown in FIG. 4B, the one or more physical properties includes a porosity p that varies over distance. Specifically, FIG. 4B shows an embodiment having a first porosity p₁ in a first region, a second porosity p₂ in a second region located between the first region and the baseplate 22, and a third porosity p₂ in a third region that is located between the second region and the baseplate 22.

In some embodiments, and as also shown in FIG. 4B, the one or more physical properties includes a thickness t that varies over distance. For example, the outer wick 38 may vary between a first thickness t₁ at a first location spaced away from the baseplate 22, and a second thickness t₂ at a second location that is between the first location and the baseplate 22, and a third thickness t₃ at a third location that is between the second location and the baseplate 22. In other words, the thickness t of the outer wick 38 may vary between a larger value closer to the baseplate 22 and a smaller value farther away from the heat source 10.

The one or more varying physical properties of the outer wick 38 may include other properties, such as composition, size, and/or shape of grains of material that comprise the outer wick 38, or size and/or shape of structural features, such as cells in a structure that comprises the outer wick 38, or any other physical property of the outer wick 38.

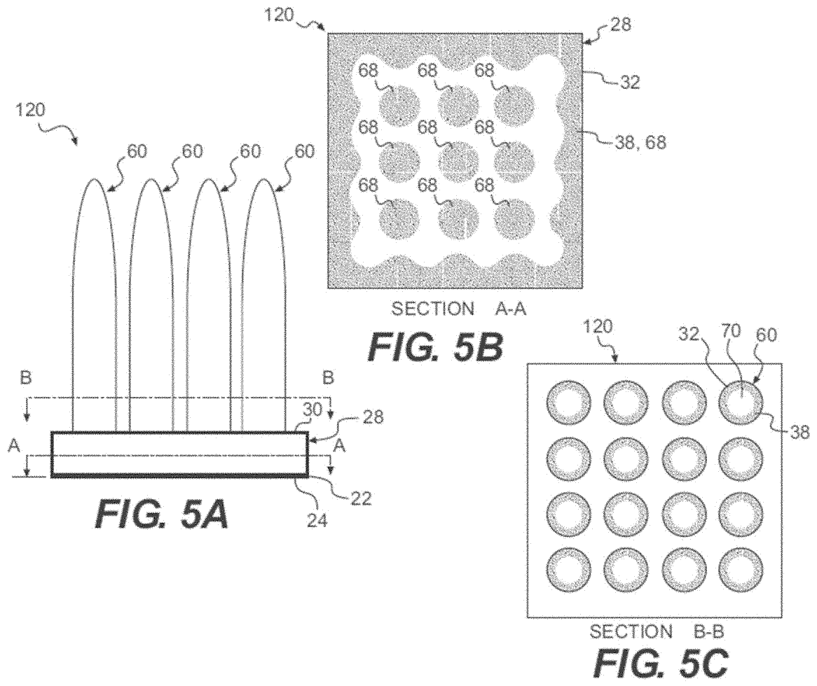

FIGS. 5A-5C, FIGS. 6A-6C, and FIG. 7 show various views of the second example heat sink 120. In some embodiments, the baseplate 22 has a square-shaped footprint of 100 mm×100 mm. The baseplate 22 may have other shapes, which may depend on application requirements. The baseplate 22 may be smaller or larger than 100 mm×100 mm. In some embodiments, each of the fins 60 may have a circular cross-section with a diameter of 15 mm. However, the fins 60 may have different shapes and/or sizes, which may be regular or irregular. In other words, different fins 60 on one heat sink 20, 120, 220 may have different shapes or sizes. The heat sink 20, 120, 220 may have a total height of 75 mm, however, the heat sink 20, 120, 220 may be smaller or larger than 75 mm in height. The foundation 28 may have a height of 25 mm between the lower surface 24 of the baseplate 22 and the cover 30. However, the foundation 28 may have a height that is less than or greater than 25 mm.

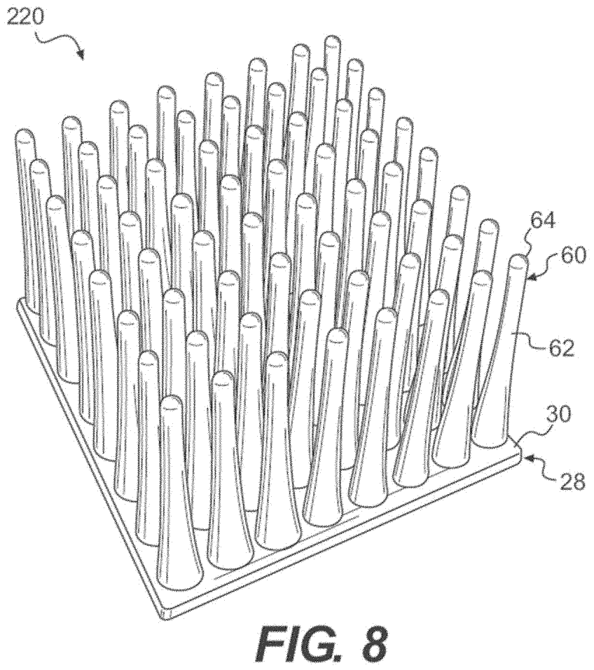

FIG. 8 shows a third example heat sink 220, which is similar to the second example heat sink 120. The third example heat sink 220 includes sixty-four fins 60 arranged in an 8×8 pattern. Each of the fins 60 of the third example heat sink 220 have a conical shape, with the body 62 tapering from a first cross-sectional area at the foundation 28 to a second, smaller cross-sectional area at the closed top 64.

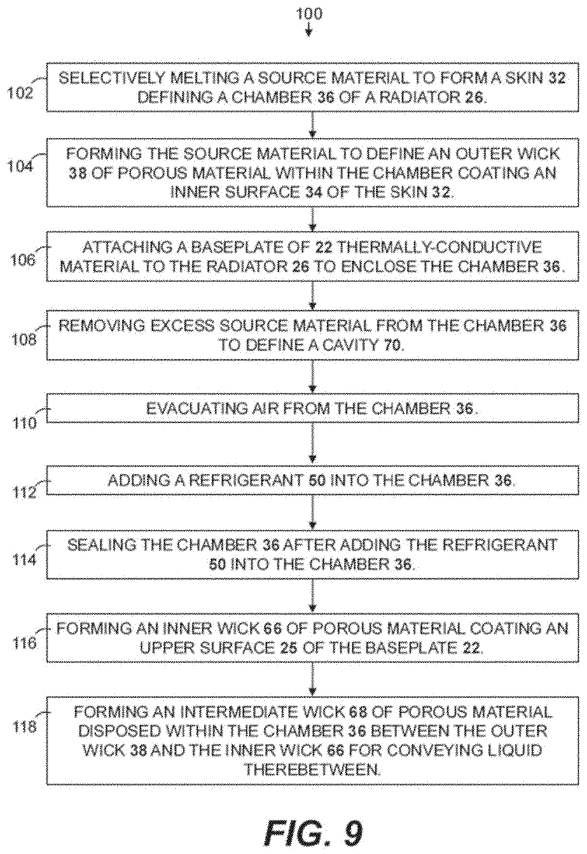

As described in the flow chart of FIG. 9, a method 100 of forming a heat sink 20, 120, 220 is also provided. The method 100 includes 102 selectively melting a source material to form a skin 32 defining a chamber 36 of a radiator 26. In some embodiments, the source material may be selectively melted using a laser.

The method 100 also includes 104 forming the source material to define an outer wick 38 of porous material within the chamber coating an inner surface 34 of the skin 32. Forming the outer wick 38 may comprise melting the source material, which may be performed as part of the same additive manufacturing process used to form the skin 32. In some embodiments, this step 104 of melting the source material to define the outer wick 38 is performed using an energy source having an intensity that is lower than an intensity used to selectively melt the source material to form the skin 32.

In some embodiments, step 104 of forming the source material to define an outer wick 38 of porous material includes varying one or more physical properties of the outer wick 38 of porous material. Varying the one or more physical properties in this step 104 may include for example, varying the process of forming the source material to define the outer wick 38, for example, using different energy levels and/or different patterns. Alternatively or additionally, varying the one or more physical properties may include varying the source material. For example, source materials having different compositions and/or different physical properties, such as grain size, may be used to form different levels of the outer wick 38. The one or more physical properties may be varied as a function of distance from a given location, such as a surface of the outer wick 38 to receive a baseplate 22. The one or more physical properties may include, for example, a thickness and/or a porosity of the outer wick 38. Alternatively or additionally, the one or more physical properties may include a grain size of the porous material and/or another physical property, such as cell size or shape of the porous material. In some embodiments, the one or more physical properties may be varied in two or more discrete steps. Alternatively or additionally, the one or more physical properties may be varied continuously as a function of distance. For example, the thickness may be varied at a constant rate or at a changing rate between a first thickness and a different second thickness over a distance.

The method 100 also includes 106 attaching a baseplate of 22 thermally-conductive material to the radiator 26 to enclose the chamber 36, wherein the baseplate 22 is configured to be in thermal communication with a heat source 10. Attaching the baseplate 22 may include forming a hermetic seal enclosing the chamber 36. The baseplate 22 may be welded to the radiator 26. Alternatively or additionally, the baseplate 22 may be attached to the radiator 26 by other means such as using an adhesive and/or using one or more fasteners.

The method 100 also includes 108 removing excess source material from the chamber 36 to define a cavity 70. The excess source material may be, for example, “green” powder that was not solidified by the additive manufacturing process. In some embodiments, the excess source material may be removed from the chamber 36 prior to attaching the baseplate of 22. For example, the excess source material may be removed from a bottom surface of the radiator 26, with the baseplate of 22 subsequently covering that bottom surface to enclose the chamber 36. In other embodiments, the excess source material may be removed from a hole through the skin 32 of the radiator 26. For example, a hole may be drilled through the skin 32 for draining the excess source material from the chamber 36 of the radiator 26. Such a hole may be plugged or filled after the excess material is removed. The source material from the additive manufacturing process may be removed from the chamber 36, for example by suction or by shaking it out of one or more holes in the baseplate 22 and/or the skin 32. Additional material may be added into the chamber 36 to comprise the permeable filling. The amount and/or the composition of the permeable filling within the chamber 36 may be selected to optimize wicking of the refrigerant 50. Alternatively or additionally, the amount and/or the composition of the permeable filling within the chamber 36 may be selected to provide structural rigidity to the heat sink 20, 120, 220, and particularly to counteract air pressure where the chamber 36 contains a vacuum.

In some embodiments, the method 100 of forming the heat sink 20, 120, 220 may further include 110 evacuating air from the chamber 36. This step may be unnecessary if, for example, the chamber 36 is formed in a vacuum, so that it contains little to no air in the first place.

In some embodiments, the method 100 of forming the heat sink 20, 120, 220 may further include 112 adding a refrigerant 50 into the chamber 36; and 114 sealing the chamber 36 after adding the refrigerant 50 into the chamber 36. Sealing the chamber 36 may be performed by attaching the baseplate 22 to the radiator 26 and/or by fixing a cap or a plug to cover a passage into the chamber 36, where the passage is used at an earlier stage for adding the refrigerant 50 into the chamber 36, and/or for evacuating air from the chamber 36. Such a passage may be formed as part of the additive manufacturing process. Alternatively, the passage may be formed, for example by drilling or puncturing, after the chamber 36 is formed. Alternatively, the passage may be integrally formed in the baseplate 22 before the skin 32 is formed.

In some embodiments, the method 100 of forming the heat sink 20 may further include 116 forming an inner wick 66 of porous material coating an upper surface 25 of the baseplate 22. In some embodiments, the method 100 of forming the heat sink 20 may further include 118 forming an intermediate wick 68 of porous material disposed within the chamber 36 between the outer wick 38 and the inner wick 66 for conveying liquid therebetween.

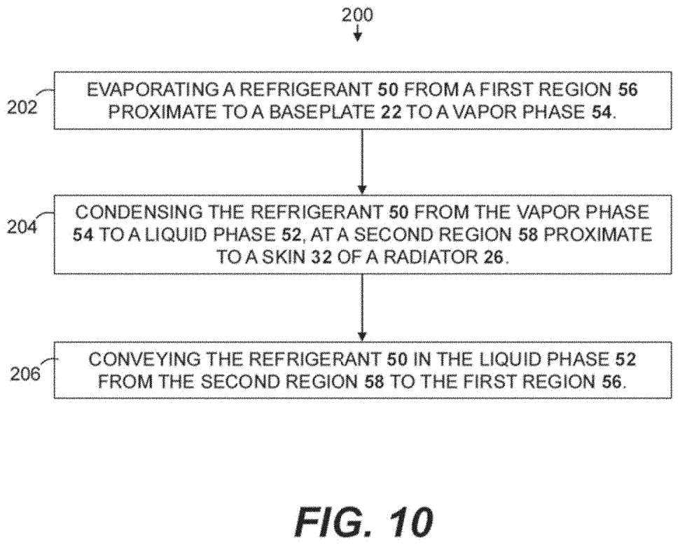

As described in the flow chart of FIG. 10, a method 200 of dissipating heat by a heat sink 20, 120, 220 is also provided. The method 200 of dissipating heat by the heat sink 20 includes 202 evaporating a refrigerant 50 from a first region 56 proximate to a baseplate 22 to a gaseous state, also called a vapor phase 54. The method 200 of dissipating heat by the heat sink 20, 120, 220 also includes 204 condensing the refrigerant 50 from the gaseous state to a liquid state, also called a liquid phase 52, at a second region 58 proximate to a skin 32 of a radiator 26.

The method 200 of dissipating heat by the heat sink 20, 120, 220 proceeds with 206 conveying the refrigerant 50 in the liquid phase 52 from the second region 58 to the first region 56. In some embodiments, the step of 206 conveying the refrigerant 50 in the liquid phase 52 is performed, at least in part, by capillary action through one or more wicks 38, 66, 68. Alternatively or additionally, the step of 206 conveying the refrigerant 50 in the liquid phase 52 may be performed, at least in part, by gravity. In this case, the heat sink 20, 120, 220 may have a preferred orientation in which it is most effective to remove heat from the baseplate 22.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A heat sink comprising:
a baseplate of thermally-conductive material defining a lower surface for conducting heat from a heat source;
a radiator disposed upon the baseplate away from the lower surface, the radiator including a skin of melted material formed by additive manufacturing and enclosing a chamber; and
an outer wick of porous material disposed within the chamber and coating an inner surface of the skin.

2. The heat sink of claim 1, wherein the outer wick comprises material melted or partially melted material by additive manufacturing.

3. The heat sink of claim 1, further comprising: a refrigerant disposed within the chamber and flowable through the outer wick.

4. The heat sink of claim 3, wherein the refrigerant is changeable between a liquid phase and a vapor phase to convey heat from the baseplate to the skin of the radiator.

5. The heat sink of claim 1, wherein the radiator includes a plurality of fins extending away from the baseplate.

6. The heat sink of claim 1, wherein at least one of the plurality of fins comprises a body shaped as a rod or a cone extending away from the baseplate to a closed top.

7. The heat sink of claim 1, further comprising an inner wick of porous material disposed within the chamber and coating an upper surface of the baseplate.

8. The heat sink of claim 7, further comprising an intermediate wick of porous material disposed within the chamber between the outer wick and the inner wick for conveying liquid therebetween.

9. The heat sink of claim 1, wherein the outer wick has a physical property that varies over a distance from the baseplate.

10. The heat sink of claim 9, wherein the physical property of the outer wick is a thickness.

11. The heat sink of claim 9, wherein the physical property of the outer wick is a porosity.

12. The heat sink of claim 9, wherein the physical property varies continuously over the distance from the baseplate.

13. The heat sink of claim 9, wherein the physical property varies in a plurality of discrete steps over the distance from the baseplate.

14. A method of forming a heat sink comprising:
selectively melting a source material to form a skin defining a chamber of a radiator;
forming the source material to define an outer wick of porous material within the chamber coating an inner surface of the skin; and
attaching a baseplate of thermally-conductive material to the radiator to enclose the chamber, wherein the baseplate is configured to be in thermal communication with a heat source.

15. The method of claim 14, further comprising removing excess source material from the chamber to define a cavity.

16. The method of claim 14, further comprising:
adding a refrigerant into the chamber; and
sealing the chamber after adding the refrigerant into the chamber.

17. The method of claim 14, further comprising forming an inner wick of porous material coating an upper surface of the baseplate.

18. The method of claim 14, wherein forming the source material to define the outer wick of porous material comprises melting the source material; and
wherein melting the source material to define the outer wick is performed using an energy source having an intensity that is lower than an intensity used to selectively melt the source material to form the skin.

19. The method of claim 14, wherein the outer wick of porous material defines a physical property that varies as a function of distance from the baseplate.

20. The method of claim 19, wherein the physical property of the outer wick is one of a thickness or a porosity.
